(19) United States
(12) Patent Application Publication
(10) Pub. No.: US 2010/0319751 A1
(43) Pub. Date: Dec. 23, 2010

(54) SERIES INTERCONNECTED THIN-FILM PHOTOVOLTAIC MODULE AND METHOD FOR PREPARATION THEREOF

(76) Inventors: Jason Day, Toledo, OH (US); Aarohi Vijh, Sylvania, OH (US); Kenneth Draeger, Toledo, OH (US)

Correspondence Address: Emch, Schaffer, Schaub & Porcello, Co., L.P.A, P.O. Box 916, Toledo, OH, 43697-0916, US

(21) Appl. No.: 12/735,268

(22) PCT Filed: Jan. 30, 2009
(86) PCT No.: PCT/US09/32747

§ 371 Date: Aug. 23, 2010

Related U.S. Application Data
(60) Provisional application No. 61/062,977, filed on Jan. 30, 2008.

(51) Int. Cl. H01L 31/042; H01L 31/04; H01L 31/18

(52) U.S. Cl. 136/244; 136/252; 136/255; 156/60; 156/150

(57) ABSTRACT

The invention provides series interconnected thin-film photovoltaic module and method of preparation thereof. The photovoltaic module includes photovoltaic cells that may be interconnected by a conductive member. The conductive member may electrically connect a top surface of a photovoltaic cell with the bottom surface of another photovoltaic cell, while contacting the photovoltaic cells along the bottom surfaces of the photovoltaic cells. The conductive member may connect the photovoltaic cells without coming between the cells. A photovoltaic cell may include an insulating layer and a collector electrode that may wrap around the side of the cell to cover at least a portion of the bottom of the cell.

### CROSS-REFERENCE

This application claims the benefit of U.S. Provisional Application No. 61/062,977, filed Jan. 30, 2008, which application is incorporated herein by reference.

### BACKGROUND OF THE INVENTION

Thin-film solar cells have been developed for use in generating electricity, and can be made in a relatively large area at relatively low cost. Thin-film solar cells have been promising for use in solar modules because they are light-weight, impact resistant, and flexible. Typical thin-film solar cells may be interconnected to form a module, wherein a conductive interconnecting member may contact the bottom surface of a first solar cell and a top surface of a second solar cell. See, e.g., U.S. Pat. No. 5,998,729 and U.S. Pat. No. 6,184,457, which are hereby incorporated by reference in their entirety. Such arrangements cause a conductive interconnecting member to come between the solar cells.

Solar modules installed outdoors may require environmental durability. In particular, flexible solar modules may be applied in situations where modules are exposed to wind and rain. Additionally, repeated flexural loads may cause stress that may cause cracks or damage to edge portions of photovoltaic devices, particularly where different points come into contact. Use of an interconnecting member between solar cells may result in damage at the edges of solar cells where the interconnecting member contacts the solar cell, especially where an interconnecting member may bend over a solar cell edge. Furthermore, interconnecting members disposed between solar cells may require a significant amount of space between solar cells to prevent solar cell damage or short circuiting.

Therefore, in view of limitations of prior art photovoltaic modules, a need exists for a solar module with interconnected solar cells that may preserve the edge portions of photovoltaic devices while providing an effective interconnection. A further need exists to provide a module that may enable flexibility in solar cell placement such that solar cells may be closely packed to provide increased energy generation per area.

### SUMMARY OF THE INVENTION

The invention provides systems and methods for series-interconnection of solar cells for photovoltaic modules. Various aspects of the invention described herein may be applied to any of the particular applications set forth below or for other types of photovoltaic or energy generation systems. The invention may be applied as a standalone system or method, or as part of an application, such as various manufacturing systems. It shall be understood that different aspects of the invention can be appreciated individually, collectively, or in combination with each other.

One aspect of the invention provides a photovoltaic module with interconnection of thin film photovoltaic cells. A conductive interconnection member may be provided that may electrically connect a top surface of a first photovoltaic cell with a bottom surface of a second photovoltaic cell. In some embodiments, the conductive interconnection member may be arranged such that it is physically connected to the first and second photovoltaic cells along the bottom surface of both cells. The first photovoltaic cell may include a collector electrode that may wrap around the cell to the bottom surface of the cell. An insulator may also wrap around the first cell between a portion of the collector electrode and the photovoltaic cell, such that the collector electrode may not contact the bottom surface of the first cell. The photovoltaic module may include interconnected thin film solar cells as described herein, and any intermediate articles thereof.

The solar cell interconnection described herein is distinct from conventional solar cell interconnections, which typically involve an interconnection member that is disposed between the solar cells to contact the top surface one a first solar cell and the bottom surface of a second solar cell. The invention provides an interconnection member that is configured to physically connect a first solar cell and second solar cell along the bottom surfaces of the cells, while being electrically connected to the top surface of one of the solar cells. The invention also provides transparent conductor (TCO) layer edge deletion such that a TCO layer does not reach an edge of a photovoltaic cell. This may result in allowing photovoltaic cells to be more closely packed together without causing a short circuit. This may also preserve edges of the photovoltaic cells because the interconnection member need not bend over the edge of the photovoltaic cell.

The invention provides a method of manufacturing a series interconnected photovoltaic module in accordance with another aspect of the invention. In some embodiments, the method of manufacturing may include providing a photovoltaic device (where TCO edge deletion may have occurred), providing an insulating layer on a selected portion of the photovoltaic device, providing a collector on the top surface of the photovoltaic device and wrapping it around to the bottom surface of the photovoltaic device, and bringing a conductive interconnecting member into contact with the collector electrode.

The method of interconnection described herein may not require that cells be fabricated with an interconnecting member that may be disposed between the cells. This may provide simplified methods of manufacture and may provide greater ease in aligning the solar cells to a desired configuration. The method may also enable closer packing of solar cells that may result in greater power generation yield per module area.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1A shows a photovoltaic sheet in accordance with one embodiment of the invention.

FIG. 1B shows a photovoltaic sheet with edge deletion in accordance with one embodiment of the invention.

FIG. 2 shows a photovoltaic sheet with a first ink layer.

FIG. 3 shows a photovoltaic sheet with a second ink layer.

FIG. 4 shows a photovoltaic sheet with an embedded conductor.

FIG. 5A illustrates a photovoltaic module with a plurality of cells and a junction box.

FIG. 5B shows a photovoltaic module with a plurality of cells and a plurality of junction boxes.

FIG. 6 shows a plurality of photovoltaic units in accordance with one embodiment of the invention.

FIG. 7 shows a part of a series interconnected photovoltaic module.

FIG. 8 shows a top view of a plurality of photovoltaic units with a bypass diode.

### DETAILED DESCRIPTION OF THE INVENTION

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The invention provides a series interconnected photovoltaic module and a method of preparation thereof. A photovoltaic module may comprise one or more photovoltaic units that may be interconnected. A photovoltaic unit may comprise a photovoltaic device (which may include a photovoltaic sheet). A photovoltaic unit may also comprise interconnecting components. The photovoltaic module may be a thin-film photovoltaic module.

Photovoltaic Module

One aspect of the invention is directed to a photovoltaic module. The photovoltaic module may include solar cells that may be interconnected. The interconnection between solar cells within a photovoltaic module may have an advantageous configuration.

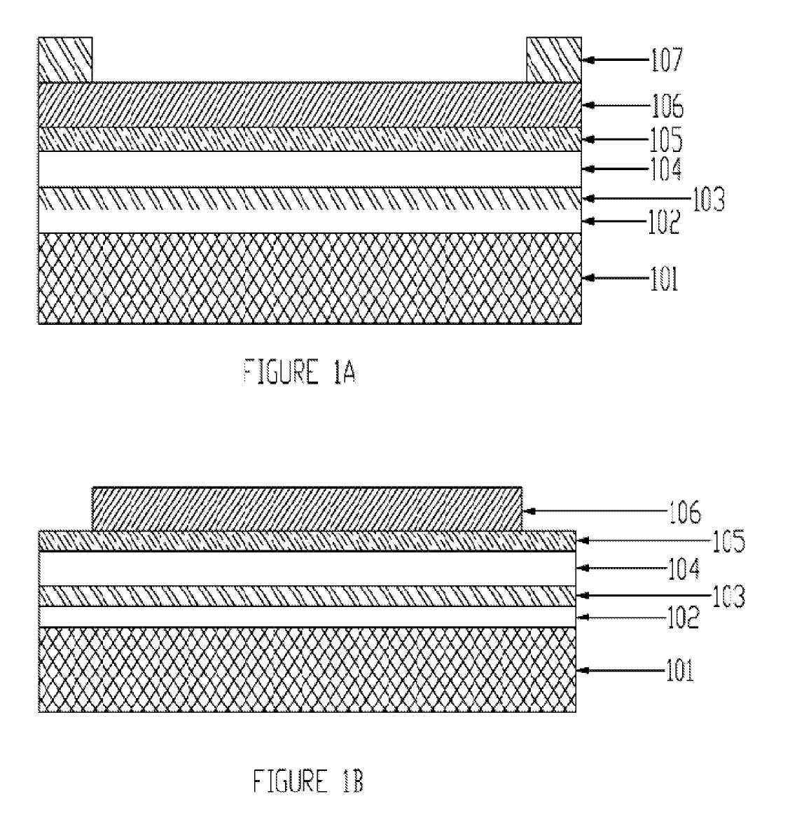

FIG. 1A shows a photovoltaic sheet in accordance with one embodiment of the invention. A photovoltaic sheet may include one or more layers. For example, a photovoltaic sheet may include a substrate layer 101, and one or more active layers. The active layers may comprise light-absorbing material. For example, the photovoltaic sheet may include three active layers 103, 104, 105, where the layers may include an n-type layer 103, an intrinsic layer 104, and a p-type layer 105. A photovoltaic sheet may also include a back reflecting layer 102 between the substrate layer and one or more active layers. A transparent conductor layer 106 may also be provided. The transparent conductor layer may be adjacent to an active layer.

The photovoltaic sheet may be formed of a first surface and a second surface opposing the first surface. For example, the first surface may be the surface of the photovoltaic sheet with a transparent conductor layer 106 and the second surface may be the surface of the photovoltaic sheet with a substrate 101. The first surface may be configured to receive light, while the second surface may be a non-light-receiving surface. In some embodiments, a first surface may be a top surface of the photovoltaic sheet and a second surface may be a bottom surface of the photovoltaic sheet, although the words “top” and “bottom” are used with respect to the photovoltaic sheet and are not limiting with respect to the orientation of the photovoltaic sheet. For example, a substrate 101 may be on the bottom of a photovoltaic sheet, while a transparent conductor layer 106 may be on the top of the photovoltaic sheet, regardless of how the photovoltaic sheet is oriented. In such a case, a first surface may be the top, light-receiving surface of the transparent conductor and a second surface may be a bottom, non-light receiving surface of the substrate.

The photovoltaic sheet may also include one or more side surfaces. A side surface may intersect the first surface and the second surface of the photovoltaic sheet. In some embodiments, a side surface may be orthogonal or substantially orthogonal to the first and second surface.

A substrate layer 101 may be formed from one or more metals, such as elemental metals. In one embodiment of the invention, the substrate layer may be a stainless steel substrate. Other examples of substrates are may include other elemental metals or metal alloy, such as aluminum, copper, iron, nickel, silver, zinc, molybdenum, titanium, tungsten, vanadium, rhodium, niobium, chromium, tantalum, platinum, gold, or any alloys, multilayers or combinations thereof, which may include a metal coated with any materials such as silver, aluminum, copper, molybdenum, iron, nickel, titanium, zinc oxide or combinations thereof, or any other substrate known or later developed in the art. In some cases, the metal substrate may have a diffusion barrier layer or anti-corrosion layer.

The substrate layer may have any thickness. For example, the substrate layer may be 5-7 mil in thickness (or approximately 127-177.8 micrometers in thickness). In other embodiments, the substrate layer may be about 0.5 mil thick, 1 mil thick, 2 mil thick, 3 mil thick, 4 mil thick, 8 mil thick, 10 mil thick, 15 mil thick, or 20 mil thick.

A back-reflecting layer 102 may be any layer that reflects solar energy incident upon it back through the active layers. This may lead to increased efficiency for a solar cell. The back-reflecting layer may be formed from any reflective materials. For example, the reflecting layer may be formed from silver or aluminum layers. The reflecting layer may also include one or more metal oxide layers, such as zinc oxide, to enhance the quality of the reflection.

The one or more active layers may be formed from semiconductor materials. In some embodiments a semiconductor forming an active layer may include materials, such as silicon-based materials such as, e.g., thin-film silicon, amorphous silicon, nanocrystalline silicon, or crystalline silicon, copper indium diselenide (CIS), copper indium gallium selenide (CIGS), cadmium telluride (CdTe), gallium indium phosphide (GaInP), gallium arsenide GaAs, and germanium Ge, and any other semiconductor material known in the art, and/or may be formed of an amorphous silicon stack, a copper indium gallium selenide (CIGS)/CdS stack, or a CdTe/CdS stack, or Cu(In, Ga)Se, ZnSe/CIS, ZnO/CIS, or Mo/CIS/CdS/ZnO. For example, one or more layers may be formed crystalline amorphous silicon or amorphous silicon-germanium semiconducting photoactive layers. Active layers may be formed of the same materials or may be formed from different materials. In some embodiments, one or more of the active layers may be doped n-type or p-type. For example, one active layer may be doped n-type while another active layer may be doped p-type. Other active layers may be undoped, or intrinsic. Doping profiles can be selected to provide a photovoltaic device with an improved quantum efficiency.

With reference to FIG. 1A, the transparent conductor layer 106 may be formed of one or more metal oxides. For instance, a transparent conductor layer 106 may include materials such as various transparent conductive oxides (TCOs) such as various tin oxides (SiOₓ), SnO₂, fluorine-doped tin oxide (SnO₂:F), indium tin oxide (ITO), zinc-oxides (e.g., zinc oxide doped with aluminum, fluorine, gallium, or boron), indium oxide, indium zinc oxide, cadmium oxide, any combinations thereof, or other transparent conducting materials known in the art, such as cadmium sulfide (CdS).

In a preferable embodiment, the thickness of any layers of the photovoltaic device may be substantially uniform. Alternatively, one or more layers of the photovoltaic device may have varying thicknesses.

A photovoltaic sheet may be provided as an intermediate step in the process of manufacturing or forming a photovoltaic cell or module.

A photovoltaic sheet may also include an etching material 107. The etching material may be on a top surface of the photovoltaic sheet. The etching material may be provided on selected portions of the photovoltaic sheet. In some instances, the etching material may be provided on selected portions of the transparent conductor layer 106. The selected portion may be any desired pattern or arrangement. In some instances, the selected portions may be along one or more edge of the photovoltaic sheet. In some implementations, the etching material may be applied along all edges of a photovoltaic sheet. In an instance where a photovoltaic sheet has a square or rectangular shape, the etching material may be applied along opposing edges or along all four edges of the photovoltaic sheet.

In some embodiments of the material, the etching material 107 may be an etch paste. For example, an etching paste may be used, such as that described in U.S. Pat. No. 5,688,366 which is hereby incorporated by reference in its entirety.

A photovoltaic sheet with an etching material may be provided as an intermediate step in the processing making or forming a photovoltaic cell or module.

FIG. 1B shows a photovoltaic sheet with edge deletion in accordance with one embodiment of the invention. An etching material may be removed from the photovoltaic sheet. A portion of a photovoltaic sheet adjacent to where an etching material was provided may be removed. For example, if an etching material were provided along all the edges of a photovoltaic sheet on a transparent conductor layer 106, a portion or all of the transparent conductor layer that was beneath the etching material may be removed. In some embodiments, a portion of an underlying layer, such as an active layer 105, may be exposed.

In some embodiments, the outside edge of the etched portion is not coincident with the edge of the photovoltaic sheet, but may rather be a few hundred micrometers away from it and parallel to it. The etched portion may have any width, and the outside or inside edge of an etched portion may be any distance from the edge of a photovoltaic sheet and may or may not be parallel to it. For example, the edges of an etched portion may be on the order of tens of micrometers away from the edge of the photovoltaic sheet, or nanometers, hundreds of nanometers, hundreds of micrometers, thousands of micrometers, or millimeters away from the edge of the photovoltaic sheet. In some instances, this etched portion may be formed by laser scribing.

In some embodiments, a photovoltaic sheet with edge deletion may include a substrate 101, a back-reflecting layer 102, one or more active layers 103, 104, 105, and a transparent conductor layer 106 that may not reach any of the edges of the photovoltaic sheet.

A photovoltaic sheet with a deleted edge may be provided as an intermediate step in the processing making or forming a photovoltaic cell or module.

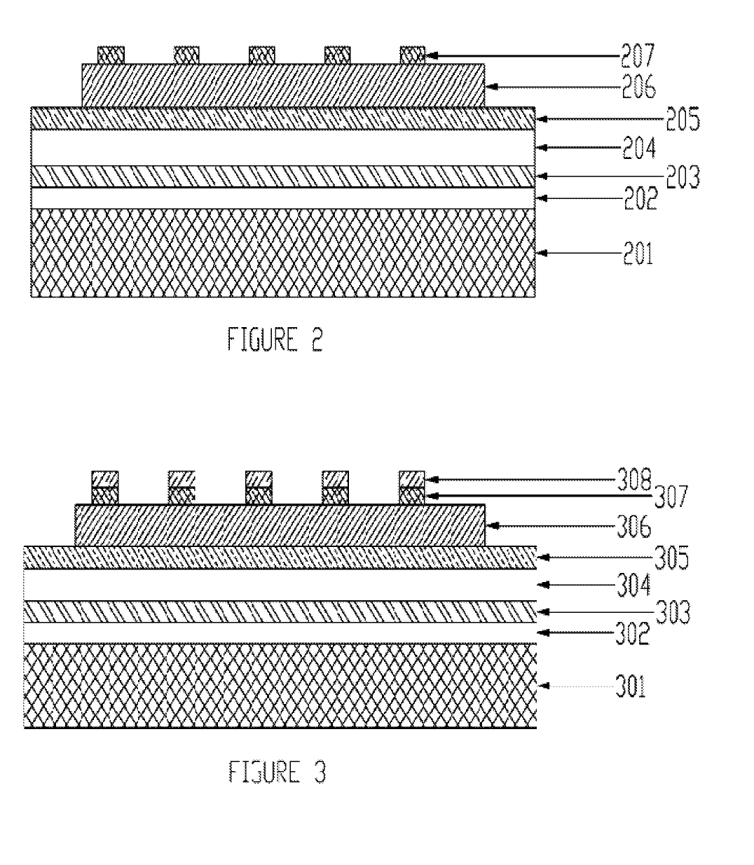

FIG. 2 shows a photovoltaic sheet with a first ink layer. A photovoltaic sheet may include a substrate 201, and one or more active layers 203, 204, 205. A photovoltaic sheet may also include a back-reflecting layer 202. Additionally, a photovoltaic sheet may include a transparent conductor layer 206. The transparent conductor layer 206 may include deleted portions such that one or active layer 205 may be exposed on the first side of the photovoltaic sheet.

An ink pattern layer 207 may be provided on the photovoltaic sheet. In a preferable embodiment of the invention, selected portions of the transparent conductor layer 206 may include ink lines or other shapes forming an ink pattern in the ink layer 207. In a preferable embodiment of the invention, a collector grid may comprise the ink layer 207. The ink layer may be a first ink layer. The first ink layer may comprise a barrier ink. Any ink pattern may be provided. For example, the ink pattern may include 100-200 micrometer wide lines spaced 4 millimeters apart on the transparent conductor layer surface.

The ink layer 207 may include line or grid formations. In some embodiments, ink lines may have a smaller width than the distance the lines are apart. For example, an ink layer may include ink lines having a width between 20-500 micrometers, 50-300 micrometers, or 130-170 micrometers. In some embodiments, the width of an ink line may be substantially uniform, while in other embodiments the width may vary. In some embodiments, the ink lines may be substantially uniformly spaced apart, while in other embodiments, the distance between the lines or the orientations of the lines may vary.

The ink layer 207 may have any thickness. In some embodiments, the ink may be between 15-25 micrometers thick, or preferably 17-25 micrometers thick. Alternatively, a first ink layer thickness may fall between 10-30 micrometers, or 5-50 micrometers. In some embodiments, the ink pattern thickness may be less than the ink pattern width.

The first ink pattern 207 may be formed of a carbon-based ink. The ink layer may be formed of other organic materials. For example, the ink may be composed of graphite particles mixed with a polymer binder or binders. Particles of silver or other metal could be used instead of graphite or carbon, or the particles may be composed of metal particles substantially coated with carbon particles. The binders used may be thermoplastic, or they could be thermosetting.

A photovoltaic sheet with a first ink layer may be provided as an intermediate step in the processing making or forming a photovoltaic cell or module.

FIG. 3 shows a photovoltaic sheet with a second ink layer. A photovoltaic sheet may include a substrate 301, and one or more active layers 303, 304, 305. While three active layers are shown, it will be appreciated that the photovoltaic sheet can include any number of active layers, such as one active layer, two active layer, four active layers, and so forth. The photovoltaic sheet may also include a back-reflecting layer 302. Additionally, the photovoltaic sheet may include a transparent conductor layer 306. The transparent conductor layer 306 may include deleted portions such that one or active layer 305 may be exposed on the top side of the photovoltaic sheet. A photovoltaic sheet may also include a first ink layer 307 on the transparent conductor layer 306 such that a portion of the transparent conductor layer is covered by the ink pattern and a portion of the transparent conductor layer is exposed on the top side of the photovoltaic sheet. The first ink layer may comprise a first ink pattern, such as a pattern of lines.

A second ink layer 308 may be provided on the photovoltaic sheet. The second ink layer may comprise a second ink pattern, such as a pattern of lines. In a preferable embodiment of the invention, the second ink layer 308 may be provided on the first ink layer 307. The second ink pattern may match the first ink pattern. For example, the second ink pattern may include lines that may have the same width and spacing as lines of the first ink pattern. In such a case, the second ink layer can directly overlay the first ink layer. The first ink pattern and second ink pattern may match a collector grid or a pattern of lines. A collector grid may comprise the first ink pattern 307 and second ink pattern 308. The second ink pattern may be an adhesive ink.

Preferably, the second ink pattern may completely cover the first ink pattern. The second ink pattern may or may not directly contact the transparent conductor layer. In other embodiments, the second ink pattern may only cover a portion of the first ink pattern. Alternatively, any ink pattern may be provided for the second ink pattern. For example, the second ink pattern may include lines having widths between about 100-200 micrometers. The lines can be spaced about 4 millimeters apart on the transparent conductor layer surface.

The second ink layer 308 may have a pattern that may include line or grid formations. In some embodiments, ink lines of the second ink layer may have a smaller width than the distance the lines are apart. In some embodiments, the ink lines of the second ink layer may have the same, smaller, or greater width than lines of the first ink layer. For example, an ink pattern may include lines with a width falling between 20-500 micrometers, 50-300 micrometers, or 130-170 micrometers. In some embodiments, the width of an ink line may be substantially uniform, while in other embodiments, the width may vary. In some embodiments, the ink lines may be substantially uniformly spaced apart, while in other embodiments, the distance between the lines or the orientations of the lines may vary. A portion of the transparent conductor layer 306 may be exposed and not covered by either a first ink pattern or a second ink pattern. For example, edge portions of the transparent conductor layer may be exposed and not covered by the first ink layer or second ink layer. Similarly, an exposed portion of an active layer 105 may remain exposed and not covered by the first ink layer or second ink layer.

The second ink layer 308 may have any thickness. In some embodiments, the ink may be between 25-50 micrometers thick. Alternatively, the second ink pattern thickness may fall between 15-60 micrometers, or 5-80 micrometers. In some embodiments, the thickness of the second ink layer may be greater than the thickness of the first ink layer.

The second ink pattern 308 may be formed of a carbon-based ink, or other organic ink. Alternatively, the second ink pattern may be formed of a conductive metal-based ink, for example a silver-based ink. In some embodiments the ink may be composed of graphite particles mixed with a polymer binder or binders. Particles of silver or other metal could be used instead of graphite or carbon, or the particles may be composed of metal particles substantially coated with carbon particles. The binders used may be thermoplastic, or they could be thermosetting.

In some embodiments, a second ink layer may be optional. For example, in some embodiments, only one ink layer, or no ink layers may be provided. In some instances, a single ink layer may function as an adhesive ink and/or a barrier ink.

A photovoltaic sheet with a first ink layer and a second ink layer may be provided as an intermediate step in the processing making or manufacturing a photovoltaic cell or module.

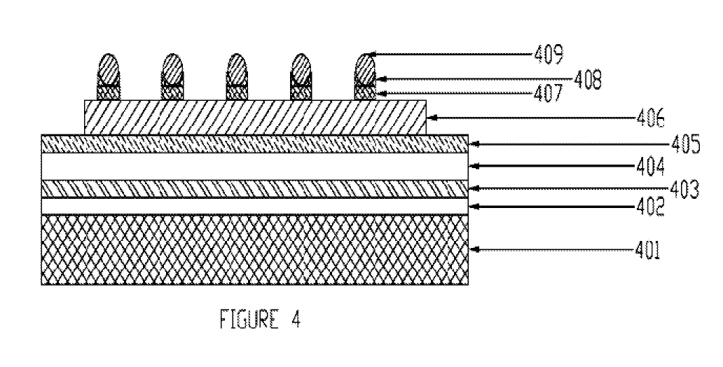

FIG. 4 shows a photovoltaic sheet with an embedded conductor. A photovoltaic sheet may include a substrate 401, and one or more active layers 403, 404, 405. The photovoltaic sheet may also include a back-reflecting layer 402. Additionally, the photovoltaic sheet may include a transparent conductor layer 406. The transparent conductor layer 406 may include deleted portions such that one or active layer 405 may be exposed on the top side of the photovoltaic sheet. A photovoltaic sheet may also include a first ink layer 407 and a second ink layer 408 (that may have a first ink pattern and second ink pattern respectively) on the transparent conductor layer 406 such that a portion of the transparent conductor layer is covered by the ink patterns and a portion of the transparent conductor layer is exposed on the top side of the photovoltaic sheet. In some embodiments, a photovoltaic device may be formed of these layers.

A conductor 409 may be provided on the photovoltaic device. In some embodiments, the conductor may be at least a part of a collector electrode of the photovoltaic device. The conductor 409 may be imbedded in the second ink layer 408. In some embodiments, the conductor may be bonded to the material (e.g., an adhesive ink) comprising the second ink layer. In some embodiments, the conductor may form part of a current collection grid. A current collection grid may be provided on the photovoltaic device and may include any material known in the art that can be used for collecting or directing current. For example, the current collection grid may include conductive glue (or conductive epoxy), conductive ink, or a metal such as copper, aluminum, nickel, gold, platinum, palladium, or silver or alloy thereof, or a conductive polymer, such as conductive plastic. With reference to FIG. 4, a current collection grid may include one or more ink layers 407, 408 and a conductor 409 in accordance with an embodiment of the invention. Any of the embodiments may be combined to form any combination of materials to provide materials for photovoltaic cells.

The conductor 409 may be provided such that it sits directly on top of the ink layers 407, 408. The conductor may have an elongated form, such as a wire form or a strip form. The placement or disposition of the conductor may conform to the placement of the ink patterns. For example, if ink patterns include lines that are about 4 millimeters apart, the conductor may be formed in lines about 4 millimeters apart. In another example, if the ink patterns have a grid form, the conductor may have a grid form. A conductor may have any pattern, and any component thereof may have any dimensions. For instance, individual lines of a conductor may have any shape or dimension. For example, a conductor may include one or more 150 micrometer diameter wire. A line (or conductor) may have any diameter, including a diameter falling within a range between 120-170 micrometers, 100-200 micrometers, or 50-300 micrometers.

A conductor may be formed from one or more elemental metals. In a preferable embodiment, the conductor may be a silver-clad copper conductor. A conductor may also include copper, aluminum, nickel, gold, platinum, palladium, or silver or alloy thereof, or any combination, arrangements, layers, or configurations thereof.

In some embodiments, a photovoltaic device may also include a protective coating of either an acrylic-based spray coat or warmed EVA (ethyl-vinyl acetate) that is provided on the surface of the PV sheet onto which the conductor 409 has been bonded through the first ink layer 407 and second ink layer 408. In one embodiment, the first ink layer is a carbon-based barrier and the second ink layer is an adhesive ink layer. The grid wires may remain exposed on the top half, i.e. they are not coated with a graphite paint. This arrangement may result in incident light being scattered in a favorable direction from this reflective surface, effectively reducing the effect of shadow losses that that may be expected from a calculation based on grid geometries. This may advantageously capture more light to be used by the photovoltaic device, which may thereby increase photovoltaic device efficiency.

The conductor 409 may form an anode for a series interconnected photovoltaic module. The conductor may also be referred to as a collector electrode.

A photovoltaic device and a collector electrode may be provided as an intermediate step in the processing making or manufacturing a photovoltaic module.

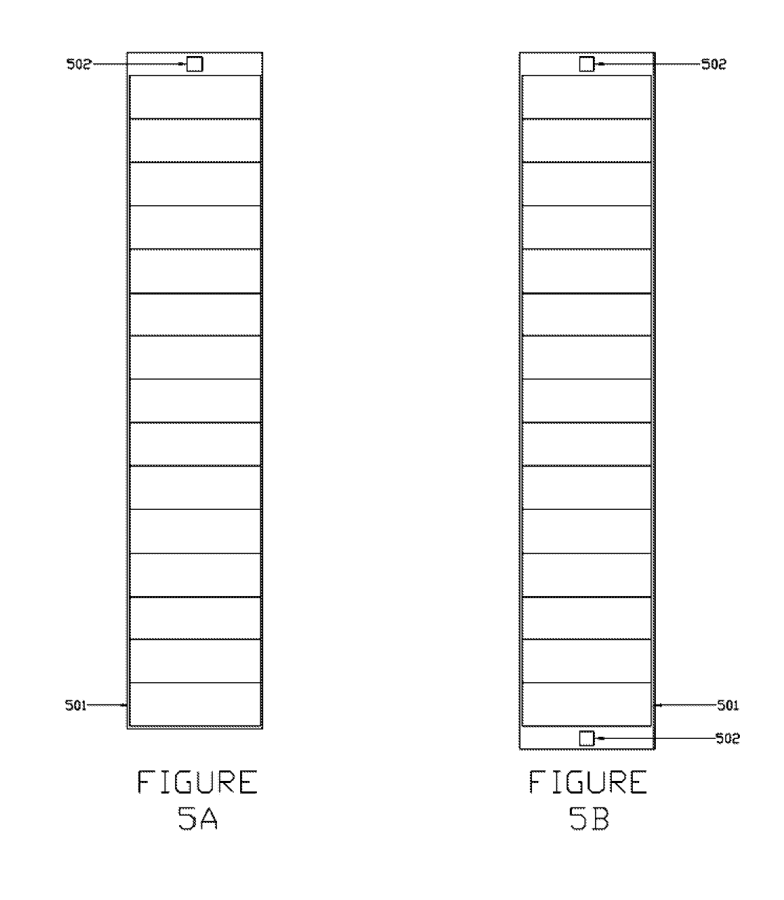

FIG. 5A illustrates a photovoltaic module with a plurality of photovoltaic cells and a junction box. While photovoltaic modules, as illustrated, may include fifteen photovoltaic cells 501, a photovoltaic module may include any number of photovoltaic cells (or strip cells). For example, one, two or more strip cells may be provided. Additionally, a photovoltaic module may include a junction box 502. FIG. 5A is a schematic diagram for a 15 cell module.

A photovoltaic cell may have the configuration of any photovoltaic cell known or later anticipated in the art. Some examples of solar cells (e.g., photovoltaic cells) include, but are not limited to, silicon cells such as monocrystalline silicon solar cells, poly- or multicrystalline silicon solar cells, thin film cells (which may include amorphous silicon, protocrystalline silicon, or nanocrystalline or microcrystalline silicon); cadmium telluride (CdTe) solar cells; copper-indium selenide (CIS) solar cells; copper indium gallium selenide (CIGS) solar cells; dye-sensitized solar cells; or organic or polymer solar cells. Also, some cells may comprise indium gallium phosphide, gallium arsenide, indium gallium arsenide, and/or germanium, and may be fabricated on a germanium substrate, a gallium arsenide substrate or an indium phosphide substrate.

A photovoltaic cell may be formed of one or more layers, including any of the arrangements described herein. For example, a photovoltaic cell may comprise photovoltaic layers and a collector electrode configuration as shown in FIG. 4.

In preferable embodiments, photovoltaic cells within a module may be interconnected in series. For example, photovoltaic cells may be arranged into a strip (e.g., as shown in FIG. 5A and FIG. 5B). In other embodiments, photovoltaic cells within a module may be connected in parallel or a combination of series and parallel. In some embodiments, the cells within a module may have any arrangement. For example, the cells of a module may form an array. The cells within the array may still be series interconnected, or interconnected in any other manner. Individual cells in an array may have any disposition with respect to one another. For example, in an array comprising a first photovoltaic cell in series with a second photovoltaic cell, the first photovoltaic cell may be disposed directly adjacent the second photovoltaic cell. Alternatively, the first photovoltaic cell may be disposed diagonally in relation to the second photovoltaic cell.

A photovoltaic module may also include a top laminate sheet over the cells. In some embodiments, the covering may provide a protective encapsulant and/or may provide mechanical support to the cells or module. In some embodiments, a back sheet or flexible laminate may also be provided below the cells. In some implementations, the lamination layer can be formed of ethyl-vinyl acetate. Alternatively, other materials, such as silicone, silicone gel, epoxy, polydimethyl siloxane, RTV silicone rubber, polyvinyl butyral, thermoplastic polyurethane, a polycarbonate, an acrylic, a fluoropolymer, a polyolefin, an urethane, or any material as known in the art may be used.

FIG. 5B shows a photovoltaic module with a plurality of cells and a plurality of junction boxes. Junction boxes 502 may be comprised of single or dual terminal devices. Junction boxes may be electrically connected to the plurality of cells. Junction boxes may facilitate wiring and may provide an ability for electrical interconnection of a photovoltaic module with another photovoltaic module or a power grid or system.

The junction boxes may include bypass diodes. The junction boxes may be affixed to the module using a RTV compound. Alternatively, the junction boxes may be affixed to the module using adhesive tape. In certain cases, a terminal may be integral to the module and may be formed during lamination.

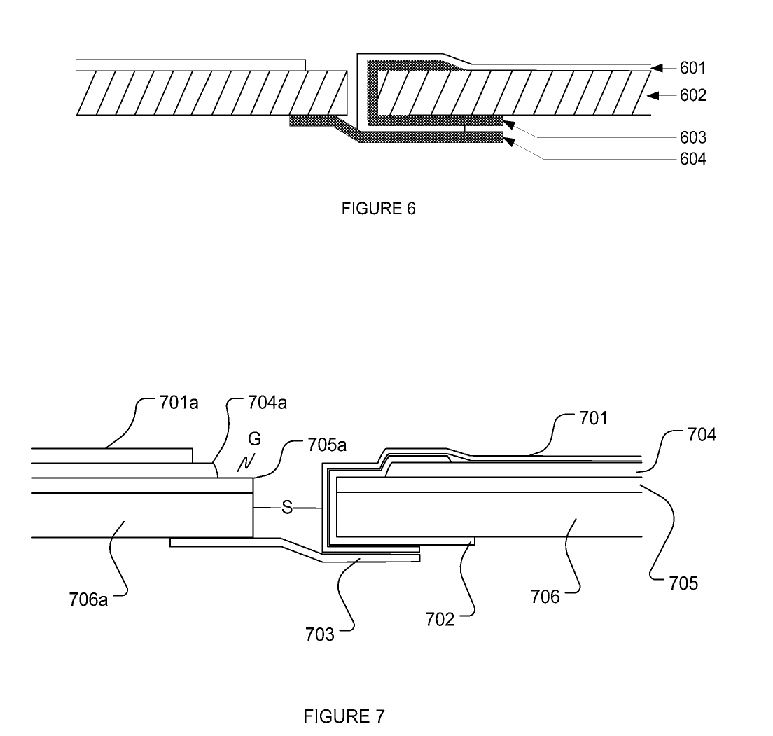

FIG. 6 shows a photovoltaic module having a first photovoltaic unit and a second photovoltaic unit in accordance with one embodiment of the invention. A photovoltaic module may have a plurality of photovoltaic units. The first photovoltaic unit may include a collector electrode 601, a photovoltaic device 602, an insulator (or insulating layer) 603, and a conductive connector 604.

A photovoltaic device 602 may include layers, such as those described elsewhere. In one example, a photovoltaic device may include layers 401-408 described previously in the context of FIG. 4. A photovoltaic device may include a substrate and one or more active layers. A photovoltaic device may also include a back-reflecting layer and a transparent conductor layer. A photovoltaic device may also include one or more ink pattern layer, or layer of other material that may enable adhesion.

A collector electrode 601 may be formed of any conducting material. In some embodiments, the collector electrode may be formed of one or more elemental metals. In some examples, a conductor 409, such as that used in FIG. 4 may be used. The collector electrode may be a silver-clad collector electrode. The collector electrode 601 may be in electrical contact with a first surface of the photovoltaic device 602. The first surface of a photovoltaic device may be configured to receive light, i.e., the first surface may be a light-receiving surface of the photovoltaic device. The collector electrode may include individual conducting elements, such as conducting lines or wires formed of a conducting material. In some examples, the collector electrode may be bonded or adhered to the surface of a photovoltaic device using an adhesion ink, or other adhesive material or technique. The collector electrode may be the same as 409.

The collector electrode affixed to the surface of the photovoltaic device may include an excess of conductor material. Any amount of excess conductor material may be provided. For example, there may be up to 2 cm excess conductor material over an insulated sheet edge. In other examples there may be about 0.001 cm, 0.01 cm, 0.05 cm, 0.1 cm, 0.2 cm, 0.5 cm, 0.8 cm, 1 cm, 1.2 cm, 1.5 cm, 1.8 cm, 2.2 cm, 2.5 cm, 3 cm, or 4 cm excess conductor material. Alternatively, the conductor electrode may not include an excess of conductor material.

An insulator 603, may include any electrically insulating material known in the art. For example, an insulating layer may be provided by an insulating tape. An insulating material may include polymeric materials such as plastic, vinyl, or rubber. The insulator could also be a thermally cured or light cured material, such as a heat cured polymer or an ultraviolet (UV) radiation cured polymer. Some other examples of insulating materials may include polyurethane, epoxy amines, and acrylates.

In one embodiment, an insulator 603 may be provided (i.e., applied, deposited, or bonded) such that it may wrap around one or more edges (or edge portions) of a photovoltaic device 602. For example, in one embodiment, an insulator may wrap over a top edge of a photovoltaic device such that it is disposed on an edge of a top surface of a photovoltaic device and at least a portion of a side surface of the photovoltaic device. In another example, an insulator may wrap over a bottom edge of a photovoltaic device such that it is disposed on at least a portion of the side surface of the photovoltaic device and a portion of a bottom surface of the photovoltaic device. An insulator may wrap around a photovoltaic device such that it is disposed on at least a portion of a top surface of the photovoltaic device, a portion of the side surface of the photovoltaic device, and a portion of a bottom surface of a photovoltaic device. As shown in FIG. 6, an insulator 603 may be disposed on a portion of a top surface of a photovoltaic device 602, on a portion of a side surface of the photovoltaic device, and on a portion of a bottom surface of the photovoltaic device. The insulator may be applied to the photovoltaic device by any method known in the art. For example, the insulator may include an adhesive side and a non-adhesive side, the adhesive side being used to adhere the insulator to the photovoltaic device.

The insulator 603 can serve various functions, such as, without limitation, preventing a collector electrode 601 from contacting (or shorting with) various layers of the photovoltaic device 602 as the collector electrode wraps around the side surface of the photovoltaic device. The insulator may also prevent a photovoltaic device from coming into contact with another photovoltaic device. In some instances, the insulator may prevent a photovoltaic device from coming into contact with a conductive connector.

As illustrated by FIG. 6, the photovoltaic device 602 may comprise a first (or top) surface, wherein the first surface is configured to receive light; a second (or bottom) surface, the second surface being a non-light-receiving surface; and at least one side surface. A side surface of a first photovoltaic device may oppose a side surface of an adjacent second photovoltaic device. While the photovoltaic device 602, as illustrated, may show one side surface, it will be appreciated that the photovoltaic device may include more than one side surface. For example, where the photovoltaic device is box-like in three dimensions, it can include four side surfaces.

In some embodiments, an insulator 603 may be disposed on an entire, or at least a portion of, a side surface of a photovoltaic device 602. For instance, an insulator may be disposed on a side surface of a photovoltaic device without contacting a top and/or bottom surface of the photovoltaic device. The insulator may be in contact with an edge portion of a top surface of the photovoltaic device, in contact with an edge portion of a bottom surface of the photovoltaic device, or in contact with both an edge portion of a top surface and an edge portion of a bottom surface of the photovoltaic device.

The insulator 603 may be disposed between at least a portion of the collector electrode 601 and the photovoltaic device 602. In some embodiments, the collector electrode 601 may have excess conductor material that may be wrapped over an insulated edge. In some embodiments, the collector electrode may be in contact with a first surface of a photovoltaic device, and not in contact with a second, opposing surface of the photovoltaic device. For instance, the collector electrode may be electrically connected to, or in electrical contact with, a top surface of a photovoltaic device, and not be in electrical contact with the bottom surface of the photovoltaic device. In some implementations, the collector electrode may be in electrical contact with a transparent conductor layer of the photovoltaic device. In other implementations, the collector electrode may be in contact with a portion or entirety of an active layer of the photovoltaic device. The collector electrode may be in electrical contact with selected portions of a photovoltaic device, such as a transparent conductor layer, without being in electrical contact with other portions of the photovoltaic device.

As shown in FIG. 6, the collector electrode 601, may be over a top surface of a photovoltaic device 602. In some embodiments, excess conductive material of the collector electrode may wrap around an edge portion of a photovoltaic device. For example, a collector electrode may wrap such that it is disposed on a top surface of a photovoltaic device and at least a portion of a side surface of the photovoltaic device. In some instances, the collector electrode may wrap around the entire portion of the side surface. An electrode may wrap around a photovoltaic device such that it is disposed on at least a portion of a top surface of the photovoltaic device, at least a portion of a side portion of the photovoltaic device, and at least a portion of a bottom surface of a photovoltaic device. In some embodiments, the electrode may be disposed over substantially the entire bottom surface of the photovoltaic device. In other embodiments, the electrode may be disposed over substantially the entire top surface of the photovoltaic device.

The excess conductive material of the electrode 601 may be folded over a first surface edge of the photovoltaic device 602, and may also additionally be folded over a second surface edge of the photovoltaic device. In some embodiments, the first surface edge may be along a top surface edge of the photovoltaic device and the second surface may be along a bottom surface edge of the photovoltaic device. The excess material may be folded about 90 degrees around the first edge, and about 90 degrees around the second edge. In some embodiments, the excess material may be folded such that it totals to being folded about 180 degrees around a photovoltaic device. In some alternate implementations, the excess material may not be folded around a second edge but may fold outwards away from the second edge, such that it forms a step-like configuration. In additional alternative embodiments, the excess material may protrude over a first edge of the photovoltaic device.

In some embodiments, the insulating layer 603 may be provided such that collector electrode material 601 covers at least a portion of the insulating layer. The electrode 601 may leave a portion of the insulator 603 exposed. Alternatively, the electrode covers the insulator in its entirety. In some embodiments, the electrode may extend beyond the insulator. In situations where excess electrode extends beyond the insulator, the excess may be arranged so as to not contact an undesirable portion of the photovoltaic device 602, such as the bottom surface.

In preferable embodiments, a conductive connector may electrically connect a light-receiving surface of a first photovoltaic device with a non-light receiving surface of an adjacent, second photovoltaic device. As shown in FIG. 6, a conductive connector 604 may electrically connect the collector electrode 601 with a bottom surface of the adjacent photovoltaic device. In certain embodiments, the connection with the bottom surface may be accomplished by laser welding.

The conductive connector 604 may be formed of any conductive material known in the art. For example, the conductive connector may include one or more elemental metals. For example, a conductive connector may include copper, aluminum, nickel, gold, platinum, palladium, or silver or alloy thereof, or any combination, arrangements, layers, or configurations thereof. A conductive connector may have any configuration known or later anticipated in the art. For example, the conductive connector may be a metal foil tab. In some implementations, the connector may be a copper tab.

The conductive connector 604 may be in contact with a collector electrode 601 of a photovoltaic unit. In some instances, the conductive connector may be in direct physical contact with the collector electrode. Alternatively, the conductive connector may be electrically connected to the collector electrode through one or more conductive materials. The conductive connector and collector electrode may be in electrical contact through a layer of solder or any other interface that may enable the conductive connector to adhere to or be affixed to the electrode.

A photovoltaic module may include a first photovoltaic unit and a second photovoltaic unit. The first photovoltaic unit may be adjacent to the second photovoltaic unit. A conductive member 604 of a first photovoltaic unit may be in electrical contact with bottom surface of the second photovoltaic unit. The conductive member 604 may be electrically connected to a first surface of a first photovoltaic unit, and electrically connected to a second surface of a second photovoltaic unit. The conductive member 604 may be electrically connected to the first surface of the first photovoltaic unit through a collector electrode 601 that may wrap around a side surface of the first photovoltaic unit. An insulator 603 may prevent the collector electrode 601 from shorting with various layers that comprise the first photovoltaic unit.

In a preferable embodiment of the invention, the conductive member 604 may be in contact with the collector electrode 601 at a location along the second surface of the photovoltaic device 602. For example, as shown in FIG. 6, a photovoltaic unit may include a photovoltaic device 602, with a top surface and a bottom surface, with an insulator 603 wrapped around a portion of the photovoltaic device, such that the insulator contacts at least a portion of the top surface, a side surface, and at least a portion of the bottom surface. A collector electrode 601 may contact the top surface of the photovoltaic device 602, and may wrap around the side of the photovoltaic device and a portion of the bottom of the photovoltaic device over the insulator 603. A conductive member 604 may contact the electrode 601 along the bottom surface of the photovoltaic device. The conductive member 604 may also contact a bottom surface of an adjacent photovoltaic unit. In some embodiments, the bottom surface of a photovoltaic device may be a substrate layer.

Therefore, in a preferable embodiment of the invention, the conductive member (or conductor member) may be electrically connected to a top surface of a first photovoltaic unit and a bottom surface of a second photovoltaic unit while physically contacting the first and second photovoltaic units along their bottom surfaces.

Thus, the invention may advantageously allow conductive members to be disposed along bottom surfaces of the photovoltaic units. A photovoltaic module may include photovoltaic units electrically interconnected by conductive members along a bottom surface of the photovoltaic units. In some embodiments, the conductive members may be arranged so that they need not be disposed between the photovoltaic units. This may have the benefit of allowing the photovoltaic units to be closer together, or may preserve edges of the photovoltaic devices.

The conductive member 604 may be disposed so that it is in electrical contact with a first surface of a first photovoltaic unit and a second surface of a second photovoltaic unit. The conductive member may not be in electrical contact with the second surface of the first photovoltaic unit when it is in electrical contact with the first surface of the first photovoltaic unit. The conductive member may also not be in electrical contact with the first surface of the second photovoltaic unit when it is in electrical contact with the second surface of the second photovoltaic unit. For example, in order to not be in electrical contact with the second surface of the first photovoltaic unit, a collector electrode 601 and/or an insulating layer 603 may be disposed between the conductive member 604 and the photovoltaic device 602. If the conductive member 604 extends beyond any of these layers, it may be configured so as to not contact the second surface of the first photovoltaic device. For example, if the conductive member extends beyond the collector electrode and the insulating layer, it can be prevented from electrically contacting the second surface of the first photovoltaic device by bending it away from the second surface of the first photovoltaic device, or having it extend straight such that a space is provided between the collector electrode and the second surface of the first photovoltaic device.

In some alternate embodiments of the invention, a conductive member may contact the electrode along the side surface of the photovoltaic device, or along a top surface of the photovoltaic device, where the top surface may be the light-receiving surface of the photovoltaic device. The conductive member may contact the electrode along one or more of the surfaces, such as the bottom surface, the side surface, or the top surface, and may be electrically connected to the top surface.

In another embodiment of the invention, an insulator may be covering at least a side portion of a first photovoltaic device. A conductive connector may provide electrical contact between a top surface of the first photovoltaic unit and a bottom surface of an adjacent second photovoltaic unit. A solar cell connector for connecting the first photovoltaic unit and the second photovoltaic unit may include the insulator and the conductive connector.

For example, in one embodiment, the conductive connector may form a clip. For example, the conductive connector may have a structure that contacts the top surface of the first photovoltaic unit, and contacts an insulator over a bottom surface of the first photovoltaic unit, and contacts the bottom surface of an adjacent second photovoltaic unit. In some embodiments, the conductive connector may contact the top surface of the first photovoltaic unit over a collector electrode or conductive wires. In other embodiment, the conductive connector may contact a transparent conductor layer of the first photovoltaic device without contacting an intermediary collector electrode or conductive wires. The conductive connector clip may include an extension that contacts a bottom surface of an adjacent second photovoltaic unit. Thus, the conductive connector clip may contact a top surface of the first photovoltaic unit and the bottom surface of the photovoltaic unit. The conductive connector clip may also be disposed over the bottom surface of the first photovoltaic unit through an insulating layer and/or over the side surface of the first photovoltaic unit through an insulating layer.

In some implementations a collector electrode 601 and conductive connector 604 may form an integral piece. For example, a single conductive assembly may contact a top surface of a first photovoltaic device and a bottom surface of a second photovoltaic device. In some embodiments, the single conductive assembly may form a clip. The clip may also be disposed over the bottom surface of the first photovoltaic device. The clip may be affixed to the bottom surface of the second photovoltaic device by being welded, soldered, or brazed to a substrate of the second photovoltaic device. In some instances, the clip may be affixed to the top surface of the first photovoltaic device by being imbedded in an adhesive ink. In some other instances, the clip may be clipped onto the first photovoltaic device, such that pressure provided by the clip around the top and bottom surfaces of the photovoltaic device may be sufficient to keep the clip connected to the first photovoltaic device. In some instances, the clip may contact or be electrically connected to a transparent conductor layer of the first photovoltaic device. Alternatively, adhesives or techniques such as welding, soldering, or brazing may be used to keep the clip affixed to the first photovoltaic device. In some embodiments, a single integral assembly that may function as a collector electrode and conductive connector may provide a robust connection between two or more photovoltaic units.

In some embodiments, a conductive connector 604 and a bottom layer of a photovoltaic device may form an integral piece. For example, a conductive connector may be an extension of the bottom surface of the second photovoltaic device. For example, the substrate of the second photovoltaic device may extend beyond one or more other layers of the second photovoltaic device. An extension of the substrate of a second photovoltaic device may have any configuration or may connect to the first photovoltaic device in any way, as discussed previously for the conductive connector. For example, an extension of the substrate may have a tab form that extends to contact a collector electrode of the first photovoltaic device along a bottom surface of the first photovoltaic device. Alternatively, the extension of the substrate can contact the collector electrode along the side or top surface of the first photovoltaic device. In some instances, the extension of the substrate can contact the first photovoltaic unit along any number of surfaces, and in some embodiments, may have a clip shape.

Preferably, the second photovoltaic unit may be adjacent to the first photovoltaic unit on the side of the first photovoltaic unit with the insulator. Alternatively, the second photovoltaic unit may be adjacent to the first photovoltaic unit on another side, such as the side opposite the side of the first photovoltaic unit with the insulator, and a conductive connector may provide electrical contact between the top surface of the photovoltaic unit and the bottom surface of the second photovoltaic unit. In this case, the second photovoltaic unit may also include an insulator covering at least a portion of the side of the second photovoltaic unit, where the insulator is on the side closest to the adjacent first photovoltaic unit. In additional alternate embodiments, the second photovoltaic unit may be adjacent to the first photovoltaic unit along a side adjacent to the side of the first photovoltaic unit with the insulator. This may enable photovoltaic cells to be series connected in various arrangements, such as right angles to one another, rather than being limited to a strip.

Additional photovoltaic units to the first and second photovoltaic units may be provided. For example, a photovoltaic module may include a third photovoltaic unit having a first, light-receiving surface and a second, non-light receiving surface. The second surface of the third photovoltaic device may be in electrical contact with the first surface of the first or second photovoltaic units through a conductive member that is in contact with the second surface of the third photovoltaic unit and in contact with a collector electrode of the first or second photovoltaic unit. Any number photovoltaic units may be provided and they may be connected using any of the interconnections discussed herein.

FIG. 7 shows a part of a series interconnected photovoltaic module. A photovoltaic module may include one, two, or more photovoltaic units. The photovoltaic units may be electrically interconnected. Preferably, the photovoltaic units within a module may be interconnected in series.

A photovoltaic unit may include a collector electrode 701, a photovoltaic device, an insulator 702, and a metal member 703.

The photovoltaic device may include layers, such as those described elsewhere. In some implementations, the photovoltaic device may be a solar cell or portion thereof. In one example, a photovoltaic device may include layers 401-408, such as those described in FIG. 4. A photovoltaic device may include a substrate 706 and one or more active layers 705. A photovoltaic device may also include a back-reflecting layer and a transparent conductor layer 704. A photovoltaic device may also include one or more ink pattern layer, or layer of other material that may enable adhesion.

The photovoltaic device may include a first surface and a second surface opposing the first surface. For example, the first surface may be the surface of the photovoltaic device with the transparent conductor layer 704 and the second surface may be the surface of the photovoltaic device with the substrate 706. In some embodiments, the photovoltaic device may have a light-receiving side and a non-light-receiving side. The non-light receiving side may be opposite the light-receiving side.

In one embodiment, a series interconnected photovoltaic module may include a first photovoltaic unit and a second photovoltaic unit. The first photovoltaic unit may be adjacent to the second photovoltaic unit. The first and second photovoltaic units may be disposed such that they are separated by a space S from one another. The space S may have any dimension. In some embodiments, the space S may be about 3 millimeters or less, 2 millimeters or less, 1 millimeter or less, 0.8 millimeters or less, 0.5 millimeters or less, 0.3 millimeters or less, 0.1 millimeters or less, 0.05 millimeters or less, 0.01 millimeters or less, or 0.001 millimeters or less. In some embodiments, the space S may be zero, such that the first and second photovoltaic units may contact or substantially contact one another. The invention may advantageously allow close-packed solar cells.

In some embodiments a series interconnected photovoltaic module may include a plurality of photovoltaic units. The photovoltaic units may be spaced apart such that the space S between them may be substantially the same for each of the photovoltaic units, or may vary from unit to unit. In some embodiments, it may be preferable to have some spacing between the units to allow flexibility of the module. Furthermore, having non-zero spacing between the units may prevent damage to the photovoltaic module when components of the module may expand during heating and contract during cooling. In other embodiments, it may be preferable for the photovoltaic units to be close-packed to provide greater coverage per surface area.

In some embodiments of the invention, a photovoltaic device may include a transparent conductor layer 704 that leaves at least a portion of the underlying layers, such as an active layer 705 below exposed. This may provide a gap G from the end of the transparent conductor layer 704 to the edge of the active layer 705. In some embodiments, a gap may be provided along the perimeter of a photovoltaic device. In some embodiments, the size of the gap G along each of the sides of the photovoltaic device may be substantially the same. Alternatively, the gap size may vary. In some embodiments, the gap size may vary along a side of the photovoltaic device, or between different sides of the photovoltaic device.

In some embodiments, the gap G may separate a portion of the transparent conducting layer 704a from a second portion of the transparent conducting layer 704a. For example, this gap may be formed from an etched or scribed portion of the transparent conducting layer that may have some distance from the edge of the photovoltaic device. In one example, a portion of the transparent conducting layer may be etched or scribed a couple of hundred of micrometers from the edge of the photovoltaic device, and parallel to it. This portion that is etched or scribed may form a gap between a portion of the transparent conductor layer closer to the edge and the portion of the transparent conductor layer further from the edge.

As shown in FIG. 7, the gap G may prevent the transparent conducting layer from coming to the edge of the photovoltaic device, which may prevent a transparent conducting layer 704a from one photovoltaic device from coming into contact with a collector electrode 701 from another photovoltaic device. Thus, in some embodiments, the space S between the photovoltaic units can be substantially small or zero without causing a short circuit between the collector electrode of one photovoltaic unit and the transparent conductor layer (or photovoltaic device, including one or more active layers) of an adjacent photovoltaic unit.

In one embodiment of the invention, a series interconnected photovoltaic module may include a first photovoltaic device with a transparent conductor layer 704a, one or more active layers 705a, and a substrate 706a, and a second photovoltaic device with a transparent conductor layer 704, one or more active layers 705, and a substrate 706. Although one active layer may be shown in FIG. 7, any number of active layers may be used. Each of the photovoltaic devices may have a light-receiving side, which may be the side with a transparent conductor layer, and a non-light-receiving side, which may be the side with a substrate. The module may also include a metal member 703 in contact with the non-light receiving side of the first photovoltaic device and electrically connected to the light-receiving side of the second photovoltaic device through a collector electrode 701 that wraps around an edge portion of the light-receiving side and the non-light-receiving side of the second photovoltaic device. The photovoltaic module may also include an insulating layer 702 that may wrap around an edge portion of the light-receiving side and the non-light receiving side of the second photovoltaic device. The insulating layer 702 may be between at least a portion of the collector electrode 701 and the second photovoltaic device. The first photovoltaic device may also include a collector electrode 701a that may wrap around the first photovoltaic device. The collector electrode 701a of the first photovoltaic device and the electrode 701 of the second photovoltaic device may contact at least a portion of the light-receiving side of the first photovoltaic device and second photovoltaic device respectively. In a preferable embodiment, the metal member 703 may contact the collector electrode 701 of the second photovoltaic device along the non-light-receiving surface of the second photovoltaic device.

The insulator 702, collector electrode 701, and metal member 703 may have any configuration or composition as described elsewhere, or as known or later developed in the art. For example, in some embodiments, a metal member 703 may contact the collector electrode 701 along a non-light receiving surface, along a side surface, and/or along a light-receiving surface of the second photovoltaic device. For instance, the metal member may contact the collector electrode at a position above the plane of the non-light receiving surface of the second photovoltaic device and between the first and second photovoltaic devices. The metal member may contact the collector electrode along a surface, such that the contact occurs close to the surface or a little away or above the surface.

In other examples, the insulator may contact a portion of the light-receiving surface and at least a portion of the side surface of the second photovoltaic unit, and may further contact a portion of the non-light-receiving surface, or may contact a portion or the entirety of a side surface, or may contact a portion of the side surface and portion of the non-light receiving surface. In some instances, an insulator may contact a transparent conductor layer 704. An insulator may cover at least a portion of a transparent conductor layer 704 and at least a portion of an active layer 705. Alternatively, an insulator need not cover or contact a transparent conductor layer, but may cover an entirety of an active layer 705. Alternatively, an insulator may cover a portion of an active layer 705, such as the active layer surface along the side surface, or no portion of the active layer. An insulator may also cover a portion of the substrate layer 706. In some embodiments, the insulator may be covering a substrate surface along the side surface and/or along the bottom surface.

A collector electrode may contact a light-receiving surface, or may contact a light-receiving surface and may wrap around a portion or entirety of a side surface, or may further wrap around a non-light receiving surface of a photovoltaic device. In a preferable embodiment, the electrode may wrap around a portion or an edge of a photovoltaic device over an insulator. Preferably, the collector electrode 701 may not directly contact a substrate 706 of the same photovoltaic device. Preferably, a space S may be provided so that a collector electrode 701 need not directly contact a substrate 706a of another photovoltaic device. In some embodiments, the space S may be zero, such that an electrode may directly contact a substrate of another photovoltaic device. If an electrode directly contacts the substrate of another photovoltaic device, a metal member 703 may not be needed, although the metal member may or may not be used. In some embodiments, the collector electrode 701 may be configured to not directly contact an active layer 705 of the same photovoltaic device.

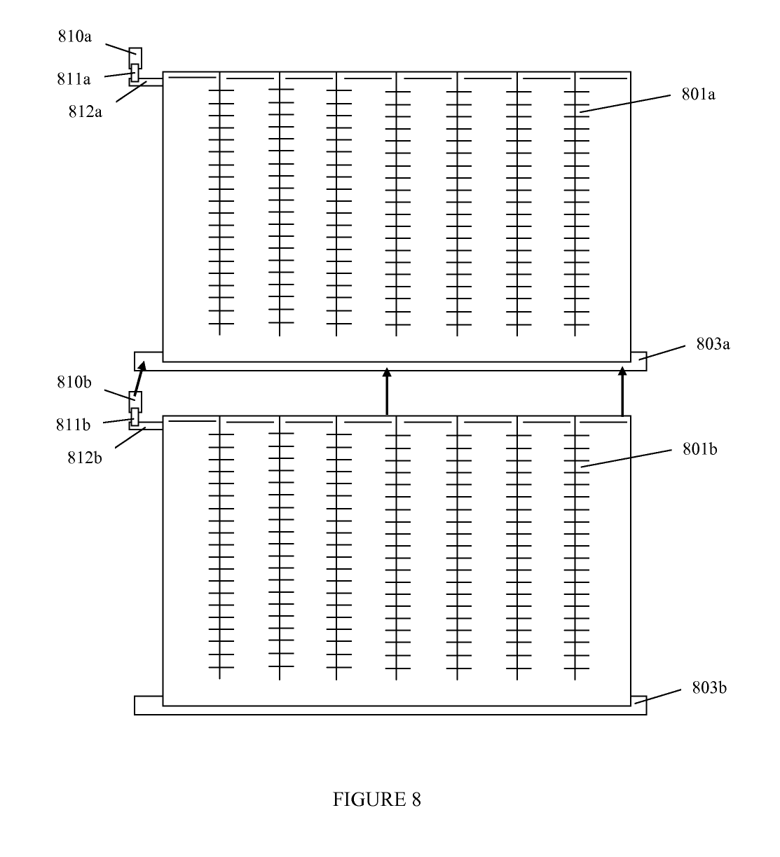

FIG. 8 shows a top view of a plurality of photovoltaic units with a bypass diode. For example, a first photovoltaic unit may include a collector electrode 801a and a conductive connector 803a. Similarly, a second photovoltaic unit may include a collector electrode 801b, and a conductive connector 803b. In some embodiments, the collector electrode may be provided by embodiments of the collector electrode and conductor described previously, such as 409, 601, or 701. In some embodiments, the conductive connector may be provided by embodiments of the connector discussed previously, such as 604 or 703.

In some embodiments, the collector electrode may function as an anode of a photovoltaic cell. For example, 801a may be an anode of a first photovoltaic cell, and 801b may be an anode of a second photovoltaic cell. In some embodiments, the conductive connector may function as a cathode of the photovoltaic cell. For example, 803a may be the cathode of the first photovoltaic cell, and 803b may be the cathode of the second photovoltaic cell. In some embodiments, the second photovoltaic cell may be brought into contact with the first photovoltaic cell, such that the collector electrode 801b of the first photovoltaic cell may come into contact with the conductive connector 803a of the first photovoltaic cell.

In some implementations, a photovoltaic cell may also include a bypass diode. For example, a first cell may include a cathode of the diode 810a, a bypass diode 811a, and an anode of the diode 812a. In some embodiments, the anode of the diode 812a may be laser welded (or attached by any other means, such as welding, soldering, brazing, adhesives, etc.) to the first cell. The anode of the bypass diode may be physically connected to the first cell. In some embodiments, the anode of the bypass diode may be physically connected to the second surface of the first cell.

A second cell may also have a cathode of the diode 810b, a bypass diode 811b, and an anode of the diode 812b. The cathode of the bypass diode 810b of the second photovoltaic cell may be brought into contact with the cathode of the first photovoltaic cell 803a. In some embodiments, the cathode of the bypass diode may be welded, soldered, or brazed or otherwise affixed to the cathode of the first photovoltaic cell. Alternatively, the cathode of the bypass diode 810b of the second cell may be brought into contact with the substrate of the first photovoltaic cell. Thus, a cathode 810b of a bypass diode may be brought into electrical communication with a substrate (which may be on the bottom surface) of the first photovoltaic cell. The anode 812b of the bypass diode may be physically connected to the second surface of the second photovoltaic cell.

Any number of photovoltaic cells may be connected in this manner to form a photovoltaic module. Thus, a plurality of photovoltaic cells may be connected between the conductive connector of a photovoltaic cell and the collector electrode of another photovoltaic cell, as well as between the conductive connector of the photovoltaic cell and a cathode of the bypass diode of the other photovoltaic cell.

In an instance where a photovoltaic cell may not be functioning, or a shadow may have fallen on a photovoltaic cell, the bypass diode may enable the current to bypass the cell. Thus, the bypass diode may enable a photovoltaic module to keep functioning even if a problem occurs with one or more photovoltaic cell of the module.

Method of Manufacture

One aspect of the invention provides for advantageous methods for forming solar cell modules.

A starting point of a process for forming a solar cell module may be a photovoltaic sheet. A photovoltaic sheet may be formed as a series of thin films deposited on to a metallic substrate to form a solar cell. The substrate may act as an electrode (e.g., a first electrode) and as a mechanical support to the thin-film layers. The thin film layers may be applied by any processing technique known in the art, such as plasma enhanced chemical vapor deposition, physical vapor deposition (e.g., magnetron sputtering), chemical vapor deposition, or atomic layer deposition.

For example, a photovoltaic sheet may be formed by a thin-film deposition, such as chemical vapor deposition. Alternatively, any other methods known in the art for creating such a structure, such as physical vapor deposition, plasma enhanced chemical vapor deposition (PECVD), atmospheric pressure chemical vapor deposition (APCVD), reduced pressure chemical vapor deposition (RPCVD), metal organic chemical vapor deposition (MOCVD), anodization, collimated sputtering, spray pyrolysis, ink jet printing, ionized physical vapor deposition, vacuum evaporation, molecular beam deposition, ion beam deposition, atomic layer deposition, electrodeposition, screen binding, hot-wire processes, sol-gel processes, screen printing, electroplating, etc. may be implemented. Such methods may also be applied to create a structure in the discussion elsewhere at any step.

The last deposited (topmost) thin film layer may be a transparent conductor (TCO), such as a metallic oxide (e.g. indium oxide, tin oxide, cadmium oxide, zinc oxide, or combinations of these, or any other material as discussed elsewhere). The TCO layer may serve as both a window (e.g., a light-receiving surface) and an electrode (e.g., a second electrode) to the cell. Thus, as shown in FIG. 1A, a photovoltaic sheet of a solar cell may include a substrate 101 and additional layers that may have been deposited or placed thereon, such as a back-reflecting layer 102, one or more active layers 103, 104, 105, and a TCO layer 106. Any of these layers may be formed of any materials known or later developed in the art, which may include materials discussed elsewhere.

The photovoltaic sheet of the cell may then processed by a series of steps into a packaged product. The series of steps and the resulting product may provide aspects of the invention. The series of steps may be applied in the order presented. Alternatively, the order of one or more of the steps may be varied for the method provided.

Step 1: TCO Edge Deletion

FIG. 1A and FIG. 1B show the edge deletion of a photovoltaic (PV) sheet. For example, a layer 107 of material, such as etching paste, may be applied (such as through screen printing) along one or more edges of the PV sheet. In some embodiments, using screen printing equipment, border of etching paste may be printed around all four edges of PV sheet. The border of the etching paste may be less than or equal to about 0.125 inches in width, although any width may be provided. A screen printing apparatus may be used to apply any amount or configuration of etching paste as desired.

Next, heat may be provided to activate the etch paste. In some embodiments, heat in the excess of 100 degrees Celsius may be provided. For example, the sheet with printed etch paste may be placed into a conveyor oven for 1 minute at elevated temperature to increase chemical activity of acid activity of etch paste. Thus, the heat may activate a chemical etch process.

After heat activation of the etch process, the TCO layer 106 along the edges may be removed as illustrated in FIG. 1B. After passing through the conveyor oven the etch paste and the etching products may be rinsed off of a PV sheet using de-ionized water. The water residue may be blown from the surface using filtered low pressure compressed air.

In alternate embodiments of the invention, the edges (or other desired portions) of the TCO layer 106 may be removed by any other techniques known or later developed in the art. For example, techniques such as laser scribing, mechanical scribing, chemical etching, lithographic etching, electro-discharge machining, or any other scribing, etching, or masking methods may be used to delete one or more edge of the TCO layer 106. For example, the edges of the TCO layer may be removed via the application of a mask followed by a chemical etch, such as a directional etch. In a preferable embodiment, edge deletion need not remove any portion of the active layer. The deleted edge may expose an active layer 105. In some embodiments, the deleted portions may not be along the edge of the TCO layer. Any desired pattern or configuration may be removed. In some instances, an etch line may be very narrow and may be between zero and 3 millimeters from the edge of the PV sheet. In some instances, a laser etch or scribe may be used to form a narrow etch line.

Step 2: Electrochemical Passivation of Shunt Sites

A PV sheet that has undergone TCO edge deletion may undergo an optional shunt passivation step. Any shunt passivation technique may be used. Some examples of methods for passivating shunting defects (or shunt sites) in a photovoltaic device is described in U.S. Patent Publication No. 2007/0256729, which is incorporated herein by reference in its entirety.

A PV sheet that has undergone an edge deletion process may include a substrate 101. The substrate may become the cathode of an electrochemical cell. In some embodiments, the substrate may be a stainless steel substrate, or may include any other substrate material known or later developed in the art. The anode of the electrochemical cell may be an aluminum mesh electrode (or electrode of any other material or arrangement). The anode may overly the TCO layer 106. The electrolyte may be an aluminum chloride solution with conductivity between 8 and 15 millisiemens per centimeter (mS/cm).

A light source may illuminate the PV cell through the aluminum mesh anode while a DC voltage may be applied across the terminal of the electrochemical cell. In some instances, the light source can illuminate the PV cell for a time period between about 1 second and 60 seconds. Following shunt passivation, the PV sheet may be removed and rinsed using de-ionized water. The rinse water may be blown off the cell. Sorting of the shunt passivated cells may then be performed.

Step 3: Processing PV Sheet into a Strip Cell or Photovoltaic Cell

FIG. 2 shows a PV sheet which has undergone edge deletion. A PV sheet that has undergone edge deletion and shunt passivation may then be modified with a printed carbon-based ink pattern 207. The ink pattern may be printed using any print technique known or later developed in the art, such as screen printing. Other techniques for applying the ink pattern may be used, including but not limited to ink-jet printing, spray coating, sputtering, manual application such as hand painting using a brush, or any other method.

The ink pattern may be printed in any desired configuration or pattern. For example, the ink pattern may include nominally 150 micrometer wide lines spaced about 4 millimeters apart.

The printed ink lines may be cured on a conveyor oven. In some embodiments, the ink may be cured to a desired thickness, such as a thickness between about 17 and 25 micrometers. Any other techniques that may involve curing or heating the ink pattern may be utilized. For example, the link lines may be heat cured or light (e.g., UV light) cured. In some embodiments, for a carbon-based ink, the ink may be cured at a temperature between about 50 degrees C. and 170 degrees C. for a time period between about 60 seconds and 600 seconds.

A second carbon-based ink layer may be printed directly over top the first printed pattern. The second ink layer may be printed using any technique known or later developed in the art, such as screen printing, or other techniques such as ink jet printing, spray coating, sputtering, manual application such as hand painting using a brush, or any other method. FIG. 3 shows an example of a PV sheet that has undergone ink deletion and that has been printed with two ink layers. A second carbon-based ink layer 308 may be an adhesive carbon-based ink. The width of the second printed layer may be matched to the width of the underlying layer. The second printed ink layer may be printed to have a desired thickness. For example, the second ink layer may be printed to be between 25 and 50 micrometers thick.

The second ink layer may be partially cured in a conveyor oven. Any other techniques that may involve curing or heating the ink pattern may be utilized. In some embodiments, for a carbon-based ink, the ink may be cured at a temperature between about 50 degrees C. and 170 degrees C. for a time period between about 60 seconds and 600 seconds. An ink may be cured at a desired temperature or length of time to achieve the desired level of curing.

FIG. 4 shows an example of a conductor that has been affixed to the PV sheet to form a PV cell. For example, after an adhesive ink layer has been printed, a conductor 409 may be imbedded and bonded into the adhesive ink layer 408. The conductor may be bonded to the ink layer by a hot press technique. Any other techniques to bond the conductor to the PV sheet may be utilized. In some embodiments, the conductor 409 may be a silver clad copper conductor.

A conductor of any form may be affixed to a PV sheet. In some implementations, a wire frame strung with nominally 150 micrometer diameter conductors may be aligned directly over-top the printed ink patterns. Each conductor may be aligned to sit directly on top of the printed lines of the inks. As mentioned previously, the conductors may be silver-clad copper conductors and the inks may be carbon-based inks. However, it will be appreciated that other materials may be used, and any discussion herein relating to silver-clad copper conductors and carbon-based inks may apply to other materials.

The assembly of the PV sheet with printed carbon-based ink lines and the silver-clad copper conductors aligned directly on top of the printed carbon-based ink lines may then be hot pressed together for a predetermined amount of time. The amount of time may be between about 1 second and 600 seconds. The hot press may soften the adhesive carbon-based ink and press the silver-clad copper conductors into the ink. Removal of the hot press may allow the ink to cool and solidify, thereby bonding the silver-clad copper conductors into the adhesive carbon-based ink printed lines.

A protective coating of either an acrylic-based spray coat or warmed EVA may be applied to the surface of the PV sheet onto which this collector electrode has been bonded through the carbon-based barrier and adhesive inks. The protective coating may be deposited by any technique known in the art, including but not limited to spray coating, brushing, or printing techniques. The silver coating on the grid wires may remain exposed on the top half, i.e. the silver coating on the top half may not be coated with graphite paint. Incident light may scatter from this reflective surface, effectively reducing the effect of the shadow loss that one would expect from a simple calculation based on grid geometry. This may advantageously allow a solar cell to operate more effectively because of the minimized shadow loss.

An insulator may be applied to a PV sheet. FIG. 7 shows one example of how an insulator 702 may be applied to the PV sheet. In some embodiments, the insulator may be an insulating tape. Any other types of insulator materials may be applied, including an insulating material with an adhesive, an insulating material that mechanically joins or provides stress to remain on the PV sheet. The insulator could also include a material that may be applied by screen printing, by ink jet printing, by spray coating, by sputtering, by manual application, such as by hand painting using a brush, or by another method, such as those discussed previously.

An insulator 702 may be fixed along one edge of the PV sheet such that it wraps around the sheet edge and onto the substrate back-side. For example, an insulating tape may be applied such that it covers at least one of the following: a portion of a top surface of the PV sheet (which may or may not cover part of a TCO layer 704 and/or active layer 705 of the PV sheet), a portion or the entirety of the side surface of the PV sheet, or a portion of the bottom surface of a substrate 706 of the PV sheet. The substrate may be a stainless steel substrate or a semiconductor substrate. An insulating tape or other insulating material may be fixed to cover a desired portion of the PV sheet.

An insulator may be applied at any step along the process. For example, the insulator may be applied after TCO edge deletion. In some cases, the insulator may be applied after shunt passivation. In another example, the insulator may be applied after one or more layers of ink layers have been printed to a PV sheet. Alternatively, the insulator may be applied after a conductor has been bonded to an adhesive ink.

A conductor forming a collector electrode may overhang an insulated edge of a PV cell. In some embodiments, a conductor attached to a PV sheet may include conductive material that does not cover the top surface of the PV sheet (i.e., excess conductive material). After an insulator and electrode conductor are affixed to a PV sheet, excess material from the conductor may be wrapped around the insulated edge of the PV cell. In some embodiments, the excess material from the conductor may remain over a top surface of the PV sheet. In other embodiments, the excess material may be folded over the top edge of the PV sheet and may go over a portion or all of the side surface of the PV sheet. In some instances, the excess material may also be folded over a bottom edge of the PV sheet and may go over a portion of the bottom surface of a PV sheet. The excess conductor material may be folded so that it does not contact the bottom surface of the PV sheet. In some embodiments, excess conductive material below the PV sheet may be prevented from contacting the bottom surface of the PV sheet via an insulator that is in contact with a portion of the bottom surface of the PV sheet.

In some embodiments, a conductive tab may provide an electrical connection between the cathode of one PV unit and the anode of an adjacent PV unit. FIG. 7 shows a first PV unit and a second PV unit. The illustrated embodiment shows how a conductive tab 703 may be connected to a substrate 706a of a PV sheet. In some embodiments, the conductive tab may be a copper metal tab and the substrate may be a stainless steel substrate. The conductive tab may be connected to the substrate using a welded electronic connection between the tab and the substrate. Any welding technique known or later developed in the art may be used, including but not limited to arc welding, gas welding, oxyfuel welding, resistance welding, spot welding, seam welding, laser beam welding, electron beam welding, ultrasonic welding, or explosion welding. Any other techniques for forming an electrical connection may be used, including but not limited to various soldering or brazing techniques.

Generally, a conductive tab may be connected to the substrate of the PV sheet at any step along the process. For example, the conductive tab may be connected to the substrate before or after TCO edge deletion. In another example, the conductive tab may be applied after one or more layers of ink layers have been printed to the PV sheet. Alternatively, the conductive tab may be applied after a conductor has been bonded to an adhesive ink. In some instances, the conductive tab may be applied after the conductor has been folded over an insulating layer. In other instances, the conductive tab may be applied after conductors have been applied to PV sheets, and PV sheets have been placed next to one another. For example, with reference to FIG. 7, after the first and second PV sheets are placed next to each other, the conductive tab 703 may be applied to the back surface of the substrate 706a and the conductor electrode 701 below the substrate 706. As another example, the conductive tab can be first applied to the back surface of the substrate 706a and subsequently applied to the collector electrode 701 below the substrate 706.

Step 4: Stringing Photovoltaic Cells into Module String and Laminating the Strings

A photovoltaic cell fabricated as per steps 1-3 above may be placed on top of a stack of backside laminate sheets on a lay-up table. The PV cell may be placed with the substrate side down. Alternatively, a PV cell may be placed on any surface with substrate side down. A bead of solder paste may be printed along the exposed part of the welded conductor tab of the photovoltaic cell. Alternatively, solder paste may be applied to the exposed part of the conductor tab using any technique known or later developed in the art. In additional alternate embodiments, any soldering technique may be used including hand soldering, hard soldering, induction soldering, wave soldering, or reflow soldering. Additionally any other techniques for joining may be used, including, welding, brazing, mechanical joining, or the use of any adhesives.

In a preferable embodiment, a first PV cell may be placed adjacent to a second PV cell. The second PV cell may include collector electrode conductor material that may be folded over PV sheet edges, such that the electrode material may overhang an insulated portion of the second PV cell and may wrap over at least a portion of the bottom surface of the second PV cell. The first PV cell may have a conductor tab attached to a bottom (non-light-receiving) surface of the first PV cell. A bead of solder paste may be applied to a portion of the conductor tab. The second cell may be positioned such that the overhanging collector electrode conductor is over the bead of solder paste. Thus, the conductor tab of the first cell with solder paste may be directly below the area of the bottom surface of the second cell covered by the electrode material.

The second PV cell may then be lowered such that a portion of the collector electrode conductors are imbedded into the bead of solder paste. When the collector electrode is brought into contact with the solder paste, the second PV cell may be disposed such that a space of no greater than 1 millimeter is formed between the substrates of the first and second PV cells when laying on a flat surface. In a preferable embodiment, the space between the first PV cell and the second PV cell may be about 1 millimeter or less. In other embodiments of the invention, the second PV cell may be lowered so that the space between the first and second PV cells are 5 mm or less, 4 mm or less, 3 mm or less, 2 mm or less, 0.5 mm or less, 0.2 mm or less, 0.1 mm or less, 0.05 mm or less, 0.01 mm or less, 0.001 mm or less, or 0 mm. In some instances, the second PV cell may be lowered to a precise desired distance from the first PV cell, while in other instances, the second PV cell may be lowered to an approximate desired distance from the first PV cell.

Heated air may be directed onto the bead of solder paste in which the collector electrode conductors are embedded, thereby electrically connecting the positive collector electrode to the negative copper metal tab of the adjacent cell. In some embodiments, the positive and negative electrodes may be connected after a period of time without the assistance of heated air.

This process may be repeated for an additional 13 photovoltaic cells thereby creating a photovoltaic string, or module, when the module comprises 15 photovoltaic cells. A series interconnected photovoltaic module may include any number of PV cells, such that the process may be repeated any number of times necessary to interconnect the PV cells within the module. For example, a module may be formed of 2 PV cells, 5 PV cells, 8 PV cells, 10 PV cells, 12 PV cells, 18 PV cells, 20 PV cells, 25 PV cells, 30 PV cells, 40 PV cells, or 50 PV cells, and may undergo the interconnecting method 1 time, 4 times, 7 times, 9 times, 14 times, 19 times, 24 times, 29 times, 39 times, or 49 times respectively. A module may be formed of n PV cells, where n is an integer greater than or equal to 1, and the interconnecting process may be repeated n-1 times to connect the PV cells within the module.

In some embodiments, the PV cells may also be connected by a bypass diode. FIG. 8 shows a top view of a plurality of cells with a bypass diode. In some embodiments, the collector electrode 801b of a second cell may be brought into contact with the conductive connector 803a of a first cell. Additionally, a cathode of a bypass diode 810b of the second cell may be brought into contact with the conductive connector 803a of the first cell.

Thus, when PV cells are interconnected, the conductive tab 803a may be the cathode of the first PV cell. The collector electrode 801a may be the anode of the first PV cell. Similarly, the conductive tab 803b may be the cathode of the second PV cell and the collector electrode 801b may be the anode of the second PV cell. The cathode of the bypass diode 810b may be connected to the conductive connector 803a of the first PV cell (or in some embodiments, the substrate of the first PV cell) through a weld connection. The anode terminal 812b of a bypass diode may be laser welded (attached by any other technique known in the art) to the backside of the second PV cell.

After PV cells are interconnected as desired, top laminate sheets may be drawn over the cells. In some embodiments, the PV cells may form an interconnected string, as shown in FIG. 5, and the top laminate sheets may be drawn over the string surface. The stacked assembly may be laminated under a vacuum or in an inert environment (e.g., in an Ar or N₂ atmosphere), or any other technique known in the art. The laminate sheet may form a protective encapsulant. In some embodiments, the lamination may provide sufficient mechanical support to the solar cells and module. The solar cells may be laminated by any material known in the art or discussed herein.

After lamination, one or more junction boxes 502 may be connected to internal metal conductors and bonded to the laminate surface. The edges of the laminated product may be trimmed to the final module specifications.

Alternative Steps

In some embodiments, a conductive connecting tab may be attached to the substrate of a PV cell. However, rather than connecting it to a collector electrode of a second PV cell along the bottom surface of the second PV cell, the conductive connecting tab may contact the collector electrode of the second PV cell anywhere along the collector electrode. For example, this may mean that the conductive connecting tab may contact the collector electrode of the second PV cell along the side surface or top surface of the second PV cell, or any combination of the surfaces of the PV cell. In some embodiments, the conductive connecting tab may be bent or have any configuration, that may enable it to contact the desired portion of the collector electrode. In a preferable embodiment, the conductive connecting tab is configured so as to not contact the bottom (non-light-receiving) surfaces of adjacent PV cells. In a preferable embodiment, the collector electrode of a PV cell is configured so as to not contact the collector electrode (or top, light-receiving surface) of an adjacent PV cell. The portion of the connecting tab to contact the electrode may have solder paste disposed thereon.

In some embodiments, a PV cell may be formed by attaching a conductive connecting tab to a collector electrode before attaching it to a substrate. For example, a PV cell may include an insulator and a collector electrode. A conductive connecting tab may be soldered or otherwise attached to the collector electrode at a desired location. In some implementations, the desired location may be the along the bottom surface of the PV cell, along the side surface of the PV cell, or along the top surface of the PV cell, or along any combination of the surfaces of the PV cell (e.g., at a location near an edge portion of the bottom surface and the side surface of the PV cell). The PV cell may be connected to another PV cell by welding or otherwise attaching the conductive connecting tab to the substrate of the other PV cell. Preferably, the tab is welded to the bottom surface of the other PV cell. In some embodiments, where the substrate of a PV cell is formed of a semiconductor material, a metal layer (e.g., elemental metal layer, metal silicide) may be provided on the bottom (non-light-receiving) surface of the substrate to provide ohmic contact between the conductive connecting tab and the substrate.

Any techniques or steps may be utilized to form a photovoltaic module as described elsewhere. Various components such as insulators, collector electrodes, or conductive connectors may be connected using any techniques known in the art to have the desired configurations.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A series interconnected photovoltaic module, comprising:
a first photovoltaic device and a second photovoltaic device adjacent the first photovoltaic device, each of the first and second photovoltaic devices having a light-receiving side and a non-light-receiving side; and
a metal member in contact with the non-light-receiving side of the first photovoltaic device and electrically connected to the light-receiving side of the second photovoltaic device through an electrode that wraps around an edge portion of the light-receiving side and an edge portion of the non-light-receiving side of the second photovoltaic device.

2. The series interconnected photovoltaic module of claim 1, wherein the first and second photovoltaic devices are less than about 1 millimeter apart.

3. The series interconnected photovoltaic module of claim 1, further comprising an insulating layer that wraps around the edge portion of the light-receiving side and the edge portion of the non-light-receiving side of the second photovoltaic device, the insulating layer being disposed between at least a portion of the electrode and the second photovoltaic device.

4. The series interconnected photovoltaic module of claim 1, wherein the electrode is in contact with at least a portion of the light-receiving side of the second photovoltaic device.

5. A photovoltaic unit, comprising:
a photovoltaic device having a first surface, a second surface opposite the first surface, and a side surface, wherein the first surface is configured to receive light;
an insulating layer disposed on an edge portion of the first surface, wherein the insulating layer wraps around the first surface and is in contact with at least a portion of the side surface;
a collector electrode disposed on at least a portion of the first surface and at least a portion of the insulating layer; and
a conductive member in electrical contact with the collector electrode.

6. A photovoltaic module comprising a plurality of the photovoltaic units of claim 5, wherein a conductive member of a first photovoltaic unit is in electrical contact with a second surface of a second photovoltaic unit adjacent to the first photovoltaic unit.

7. The photovoltaic module of claim 6, wherein the first photovoltaic unit and the second photovoltaic unit are less than about 1 millimeter apart.

8. The photovoltaic module of claim 6, further comprising a bypass diode, wherein the anode of the bypass diode is physically connected to the first photovoltaic unit, and the cathode of the bypass diode is in electrical communication with the second surface of the second photovoltaic unit.

9. The photovoltaic unit of claim 5, wherein the conductive member is in electrical contact with the collector electrode at a location along the second surface of the photovoltaic device.

10. The photovoltaic unit of claim 5, wherein the insulating layer wraps around the side surface and is in contact with an edge portion of the second surface.

11. The photovoltaic unit of claim 5, wherein at least one of the conductive member or the collector electrode is formed of one or more elemental metals.

12. The photovoltaic unit of claim 5, wherein the photovoltaic device comprises a substrate and a layer of semiconductor material over the substrate.

13. The photovoltaic unit of claim 12, wherein the photovoltaic device further comprises a back reflecting layer between the substrate and the layer of semiconductor material.

14. The photovoltaic unit of claim 12, wherein the substrate is formed of one or more elemental metals.

15. A solar cell connector for a photovoltaic module, comprising:
an insulator for substantially covering a side surface of a first photovoltaic unit; and
a conductive connector for electrical contact between a top surface of the first photovoltaic unit and a bottom surface of a second photovoltaic unit.

16. A method for forming a photovoltaic module, comprising:
bringing a conductive member in contact with the collector electrode, wherein the collector electrode is in contact with at least a portion of a top surface of the photovoltaic device, and wherein the collector is insulated from a side surface of the photovoltaic device via an insulating layer disposed on an edge portion of the top surface of the photovoltaic device and the side surface of the photovoltaic device.

17. The method of claim 16, wherein the photovoltaic device comprises a substrate and one or more active layers over the substrate.

18. The method of claim 17, wherein the photovoltaic device further comprises a back-reflecting layer over the substrate and below the one or more active layers.

19. The method of claim 17, further comprising forming a transparent conductor layer over the one or more active layers of the photovoltaic device.

20. The method of claim 19, wherein the transparent conductor layer is formed of one or more metal oxides.

21. The method of claim 19, wherein the transparent conductor layer does not cover a portion of the one or more active layers along an edge portion of the top surface.

22. The method of claim 16, wherein providing the photovoltaic device comprises electrochemically passivating shunt sites of the photovoltaic device.

23. A method for forming a series interconnected photovoltaic module, comprising:
providing a first photovoltaic device and a second photovoltaic device, each having a light-receiving surface, a side surface and a non-light-receiving surface;
providing an insulating layer on an edge portion of the light-receiving surface of the first photovoltaic device and the side surface of the first photovoltaic device;
providing an electrode on the light-receiving surface of the first photovoltaic device and the insulating layer, wherein the electrode is over the side surface of the first photovoltaic device;
bringing a metal member in contact with the non-light-receiving surface of the second photovoltaic device; and
bringing the metal member in contact with the electrode.

24. The method of claim 23, further comprising providing a third photovoltaic device adjacent to the second photovoltaic device, the third photovoltaic device having a light-receiving surface, a side surface and a non-light-receiving surface.

25. The method of claim 24, further comprising bringing a second metal member in contact with the non-light-receiving surface of the third photovoltaic device and an electrode that is in electrical contact with the light-receiving surface of the second photovoltaic device.
